(19) United States
(12) Patent Application Publication
(10) Pub. No.: US 2021/0098497 A1
(43) Pub. Date: Apr. 1, 2021

(54) ARRAY SUBSTRATE AND FABRICATING METHOD THEREOF

(71) Applicant: TCL China Star Optoelectronics Technology Co., Ltd., Shenzhen, Guangdong (CN)

(72) Inventor: Xiaobo HU, Shenzhen, Guangdong (CN)

(21) Appl. No.: 16/615,532

(22) PCT Filed: Sep. 25, 2019
(86) PCT No.: PCT/CN2019/107934

§ 371 Date: Nov. 21, 2019

(30) Foreign Application Priority Data
Jun. 6, 2019 (CN) 201910491312.X

(51) Int. Cl. H01L 27/12; C23C 14/14; C23C 14/02; C23C 14/04; C23C 14/24; C23C 14/54

(52) U.S. Cl. CPC H01L 27/124; C23C 14/14; C23C 14/025; H01L 27/1259; C23C 14/24; C23C 14/541; C23C 14/542; C23C 14/04

(57) ABSTRACT

This disclosure provides an array substrate and a fabricating method thereof. After metal traces are recrystallized from the molten state, sizes of metal grains constituting the metal traces become larger, and the grain boundaries and defects of the film layer of the metal traces are reduced, thereby reducing the degree of scattering of electrons during the transmission in the metal traces, reducing the resistivity of the metal traces, improving the conductivity of the metal traces and the array substrate, and reducing the thickness of the metal layer forming the metal traces.

### FIELD OF INVENTION

This invention relates to the field of display technologies, and, in particular, to an array substrate and a fabricating method thereof.

### BACKGROUND OF INVENTION

With development of flat panel display technology, people's pursuit of display device size, resolution and picture refresh rate is getting higher and higher, so using copper with a lower resistivity to replace aluminum with a higher resistivity has become a trend.

The mechanism of metal film conduction is that there are a large number of free electrons inside, and these electrons are oriented to move under the action of an electric field to form a current, so that the metal film can conduct electricity. The conductivity of a metal depends mainly on the binding of metal atoms to electrons and the scattering of electrons at grain boundaries and defects during transmission.

### Technical Problems

In fabrication process of thin film transistors (TFT), copper films are generally deposited by physical vapor deposition (PVD) sputtering. The thin film transistors and array substrate film formed by PVD are mostly polycrystalline, and there are many defects, which leads to problem that the conventional thin film transistors and the array substrate have large metal trace resistance and weak conductive ability.

In summary, the conventional array substrate has a problem that metal trace resistance is large and conductivity is weak. Therefore, it is necessary to provide an array substrate and a fabricating method to improve this defect.

### Technical Solution

The embodiment of the present disclosure provides an array substrate and a manufacturing method thereof, which are used to solve the problem that resistance of metal traces of the conventional array substrate is large and the conductivity is weak.

The embodiment of the present disclosure provides a method of fabricating an array substrate, including a plurality of steps of:

step S10: providing a substrate, and depositing and forming a metal layer on the substrate;

step S20: patterning the metal layer to form metal traces; and

step S30: disposing the substrate in a vacuum chamber, and performing a heat treatment process to recrystallize the metal traces.

According to an embodiment of the present disclosure, material of the metal layer includes Cu, Al, or Mo, or an alloy of two or more than two metals of Cu, Al, and Mo.

According to an embodiment of the present disclosure, the metal layer includes a first metal layer and a second metal layer, the first metal layer is disposed on the substrate, and the second metal layer is disposed on a side of the first metal layer away from the substrate.

According to an embodiment of the present disclosure, material of the first metal layer is Mo, a thickness of the first metal layer ranges from 100 A to 1000 A, material of the second metal layer is Cu, and a thickness of the second metal layer ranges from 1000 A to 10000 A.

According to an embodiment of the present disclosure, in the step S30, the substrate is heat-treated at a temperature ranging from 200° C. to 450° C.

According to an embodiment of the present disclosure, in the step S30, the substrate is heat-treated for 5 minutes to 300 minutes.

According to an embodiment of the present disclosure, the method further includes:

step S40: depositing and forming a gate insulating layer and a semiconductor layer on the metal layer in order;

step S50: depositing and forming a source/drain electrode layer on the semiconductor layer, and patterning the source/drain electrode layer to form a source electrode and a drain electrode;

step S60: disposing the substrate in the vacuum chamber, and performing a heat treatment process to recrystallize the source electrode and the drain electrode; and

step S70: depositing and forming a protective layer and a pixel electrode layer on the source electrode, the drain electrode, and the semiconductor layer.

According to an embodiment of the present disclosure, in the step 10, the metal layer is deposited by physical vapor deposition.

The embodiment of the present disclosure provides a method of fabricating an array substrate, including a plurality of steps of:

step S10: providing a substrate, and depositing and forming a first metal layer and a second metal layer on the substrate in order, the first metal layer being disposed on the substrate, and the second metal layer being disposed on a side of the first metal layer away from the substrate;

step S20: patterning the first metal layer and the second metal layer to form metal traces; and

step S30: disposing the substrate in a vacuum chamber, and performing a heat treatment process to recrystallize the metal traces.

According to an embodiment of the present disclosure, materials of the first metal layer and the second metal layer include Cu, Al, or Mo, or an alloy of two or more than two metals of Cu, Al, and Mo.

According to an embodiment of the present disclosure, material of the first metal layer is Mo, a thickness of the first metal layer ranges from 100 A to 1000 A, material of the second metal layer is Cu, and a thickness of the second metal layer ranges from 1000 A to 10000 A.

According to an embodiment of the present disclosure, in the step S30, the substrate is heat-treated at a temperature ranging from 200° C. to 450° C.

According to an embodiment of the present disclosure, in the step S30, the substrate is heat-treated for 5 minutes to 300 minutes.

According to an embodiment of the present disclosure, the method further includes:

step S40: depositing and forming a gate insulating layer and a semiconductor layer on the metal layer in order;

step S50: depositing and forming a source/drain electrode layer on the semiconductor layer, and patterning the source/drain electrode layer to form a source electrode and a drain electrode;

step S60: disposing the substrate in the vacuum chamber, and performing a heat treatment process to recrystallize the source electrode and the drain electrode; and

step S70: depositing and forming a protective layer and a pixel electrode layer on the source electrode, the drain electrode, and the semiconductor layer.

According to an embodiment of the present disclosure, in the step 10, the metal layers are deposited by physical vapor deposition.

The embodiment of the present disclosure further provides an array substrate, including:

a substrate;

a gate line layer disposed on the substrate;

a gate insulating layer disposed on the substrate and covering the gate line layer;

a semiconductor layer disposed on a side of the gate insulating layer away from the substrate; and

a source/drain electrode layer disposed on a side of the semiconductor layer away from the substrate;

wherein materials of the gate line layer and the source/drain electrode layer are both a conductive metal, the gate line layer is a recrystallized gate line layer, and the source/drain electrode layer is a recrystallized source/drain electrode layer.

According to an embodiment of the present disclosure, materials of gate line layer and the source/drain electrode layer include Cu, Al, or Mo, or an alloy of two or more than two metals of Cu, Al, and Mo.

### BENEFICIAL EFFECT

The beneficial effects of the disclosure: in the embodiment of the present disclosure, the metal layer deposited on the substrate is formed into metal traces by a patterning process, and subjected to a heat treatment process to recrystallize metal grains in the metal traces. After the metal traces are recrystallized from molten state, sizes of the metal grains constituting the metal traces become larger, and the grain boundaries and defects of the film layer of the metal traces are reduced, thereby reducing the degree of scattering of electrons during the transmission in the metal traces, reducing the resistivity of the metal traces, and improving the conductivity of the metal traces and the array substrate. Due to the improvement of the conductivity of the metal traces, the thickness of the metal layer forming the metal traces can be reduced, the rigidity of the metal layer to warp the substrate can be reduced, and the production efficiency of the physical vapor deposition machine can be improved.

### DESCRIPTION OF DRAWINGS

In order to more clearly illustrate the technical solutions in the embodiments or the prior art, the drawings to be used in the embodiments or the prior art will be briefly described below. It will be apparent that the drawings in the following description are merely some of the embodiments disclosed, and other figures may be obtained based on these by those skilled in the art without any creative work.

FIG. 1 is a schematic flowchart of a method for fabricating an array substrate according to embodiment 1 of the present disclosure.

FIG. 2 is a cross-sectional view showing a structure of the array substrate according to embodiment 1 of the present disclosure.

FIG. 3 is a cross-sectional view showing the structure of the array substrate according to embodiment 1 of the present disclosure.

FIG. 4 is a schematic flowchart of a method for fabricating an array substrate according to embodiment 1 of the present disclosure.

FIG. 5 is a cross-sectional view showing the structure of the array substrate according to embodiment 1 of the present disclosure.

FIG. 6 is a cross-sectional view showing a structure of an array substrate according to embodiment 2 of the present disclosure.

### DETAILED DESCRIPTION OF PREFERRED EMBODIMENTS

The following description of the various embodiments is provided to illustrate the specific embodiments of the application. Directional terms mentioned in the present invention, such as “top”, “bottom”, “front”, “back”, “left”, “right”, “inside”, “outside”, “side”, etc., are merely directions of the figures. Therefore, the directional terms are used for the purpose of illustration and understanding of the application rather than limiting the application. In the figures, structurally similar elements are denoted by the same reference numerals.

The disclosure will be further described below in conjunction with the accompanying drawings and specific embodiments:

### Embodiment 1

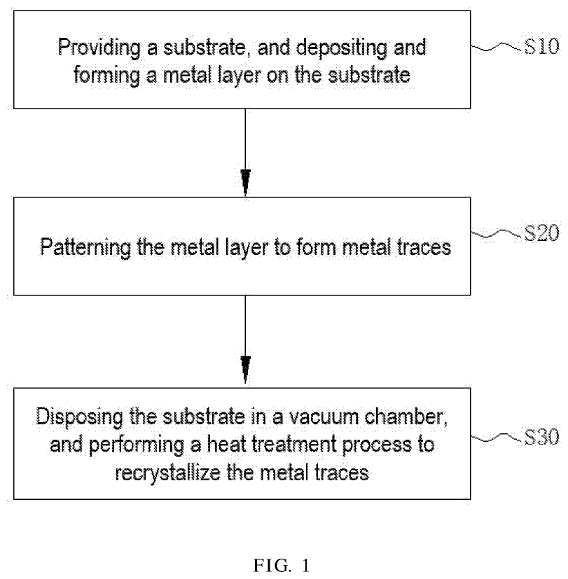

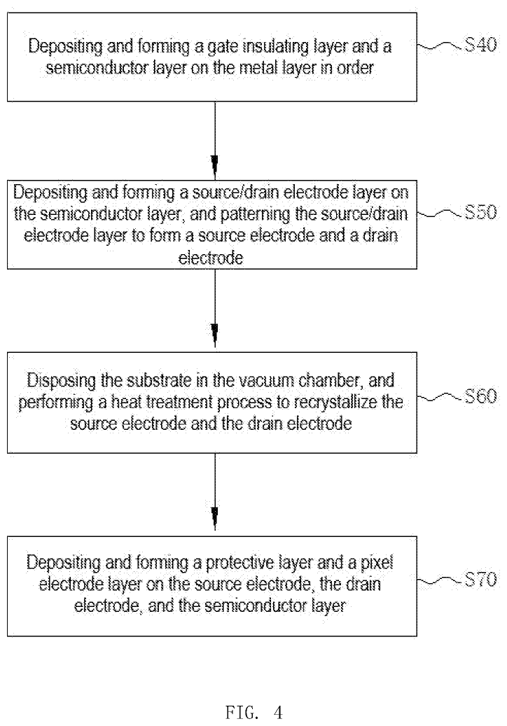

The embodiment of the present disclosure provides a method for fabricating an array substrate, which will be described in detail below with reference to FIGS. 1 to 5.

As shown in FIG. 1, FIG. 1 is a schematic flowchart of method for fabricating an array substrate 100 according to the embodiment of the disclosure, the method includes:

Step S10: providing a substrate 110, and depositing and forming a metal layer 120 on the substrate 110. Wherein in the step S10, the metal layer is deposited by physical vapor deposition.

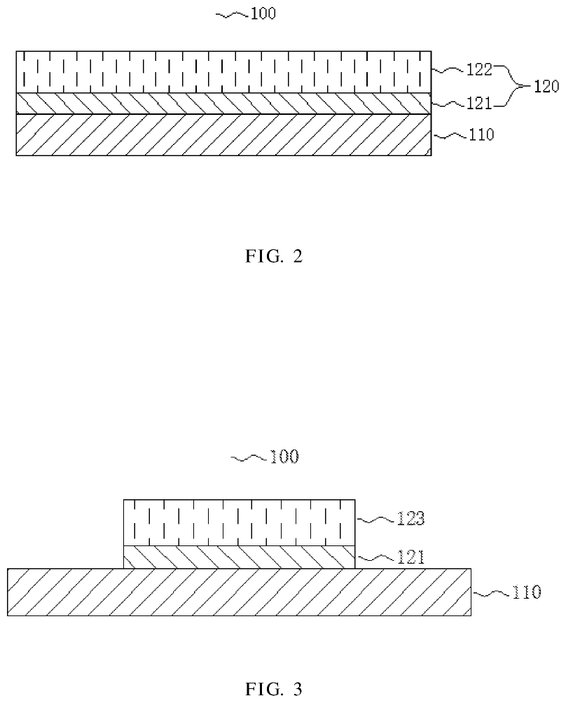

Specifically, as shown in FIG. 2, FIG. 2 is a cross-sectional view of the array substrate according to the embodiment of the disclosure. The metal layer 120 includes a first metal layer 121 and a second metal layer 122, the first metal layer 121 is used as a barrier layer and disposed on the substrate 110, the second metal layer 122 is used as a conductive layer and disposed on a side of the first metal layer 121 away from the substrate 110.

In this embodiment, in order to improve the conductivity of the array substrate 100, Cu having a lower resistance is selected as material of the second metal layer 122, and in order to prevent Cu atoms in the second metal layer 122 from being diffused to other layers such as an active layer and a gate insulating layer under the action of a high temperature or an applied electric field, the performance of other device layers of the array substrate is degraded or even ineffective, so that metal Mo having a high melting point, good thermal stability and electrical conductivity is selected as material of the first metal layer 121.

Specifically, a thickness of the first metal layer 121 ranges from 100 A to 1000 A, and a thickness of the second metal layer 122 ranges from 1000 A to 10000 A.

In some other embodiments, the material of the metal layer 120 may also include, but not limited to, Cu, Al or Mo, or an alloy of any two or more than two metals of Cu, Al and Mo.

Step S20: patterning the metal layer 120 to form metal traces 123.

Specifically, in the step S20, the metal layer 120 is exposed, developed, and etched, the second metal layer 122 is etched into a pattern of the desired metal traces 123 as shown in FIG. 3, the first metal layer 121 follows the second metal layer 122 to be etched, and the first metal layer 121 still acts as a barrier layer to exert its function of blocking the diffusion of Cu atoms.

Step S30: disposing the substrate in a vacuum chamber, and performing a heat treatment process to recrystallize the metal traces.

In the step S30, the substrate is disposed in a vacuum chamber and a heat treatment process is performed for the purpose of utilizing high temperature to cause metal grains in the metal traces 123 to become molten and recrystallized. During this process, sizes of metal grains constituting the metal traces 123 become larger, and the grain boundaries and defects of the film layer of the metal traces 123 are reduced, thereby reducing the degree of scattering of electrons during the transmission in the metal traces 123, reducing the resistivity of the metal traces 123, and improving the conductivity of the metal traces 123 and the array substrate 100. Due to the improvement of the conductivity of the metal traces 123, the thickness of the metal layer 120 forming the metal traces 123 can be reduced, the rigidity of the metal layer 120 to warp the substrate 110 can be reduced, and the production efficiency of the physical vapor deposition machine can be improved.

Specifically, in the step S30, the substrate is heat-treated at a temperature ranging from 200° C. to 450° C., and the substrate is heat-treated for 5 minutes to 300 minutes.

In the embodiment, the fabricating method further includes:

Step S40: depositing and forming a gate insulating layer 130 and a semiconductor layer 140 on the metal layer 120 in order;

Step S50: depositing and forming a source/drain electrode layer on the semiconductor layer 140, and patterning the source/drain electrode layer to form a source electrode 150 and a drain electrode 151;

Step S60: disposing the substrate 110 in the vacuum chamber, and performing a heat treatment process to recrystallize the source electrode 150 and the drain electrode 151; and

Step S70: depositing and forming a protective layer 160 and a pixel electrode layer 170 on the source electrode 150, the drain electrode 151, and the semiconductor layer 140.

As shown in FIG. 5, FIG. 5 is a cross-sectional view showing the structure of the array substrate according to an embodiment of the present disclosure. The pixel electrode layer 170 is connected to the drain electrode 151 through a first via hole on the protective layer 160.

In this embodiment, the material of the source/drain electrode layer is metal Cu. Therefore, the principle of step S60 is the same as that of step S30, and the metal crystal grains in the source electrode 150 and the drain electrode 151 in the source/drain electrode layer are recrystallized by the heating process in the vacuum chamber, thereby achieving the same technical effect as that of step S30, that is, the thickness of the source/drain electrode layer can be reduced while improving the conductivity of the source electrode 150 and the drain electrode 151.

In the embodiment of the present disclosure, the metal layer 120 deposited on the substrate 110 is formed into metal traces 123 by a patterning process, and subjected to a heat treatment process to recrystallize metal grains in the metal traces 123. After the metal traces 123 are recrystallized from molten state, sizes of the metal grains constituting the metal traces 123 become larger, and the grain boundaries and defects of the film layer of the metal traces 123 are reduced, thereby reducing the degree of scattering of electrons during the transmission in the metal traces 123, reducing the resistivity of the metal traces 123, and improving the conductivity of the metal traces 123 and the array substrate 100. Due to the improvement of the conductivity of the metal traces 123, the thickness of the metal layer 120 forming the metal traces 123 can be reduced, the rigidity of the metal layer 120 to warp the substrate 110 can be reduced, and the production efficiency of the physical vapor deposition machine can be improved.

### Embodiment 2

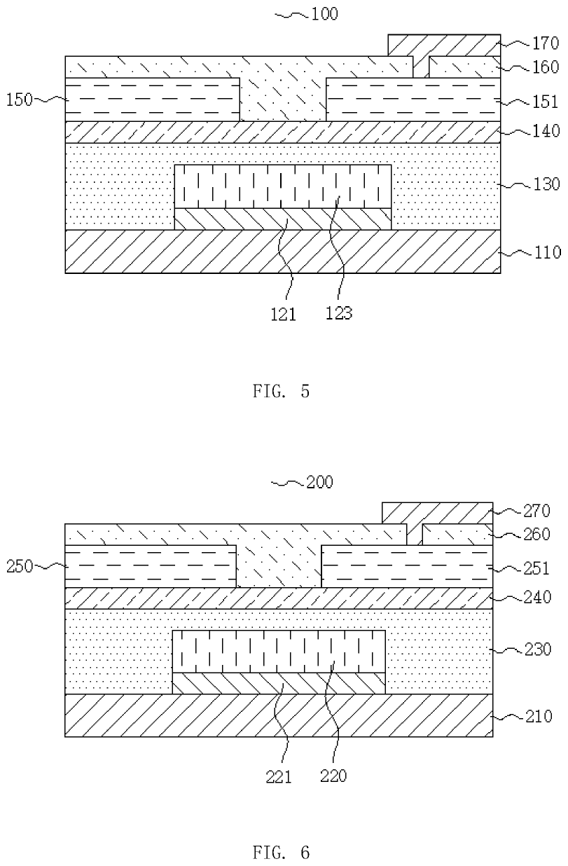

The embodiment of the present disclosure further provides an array substrate, which will be described in detail below with reference to FIG. 6.

As shown in FIG. 6, FIG. 6 is a cross-sectional view showing a structure of an array substrate 200 according to an embodiment of the present disclosure. The array substrate 200 includes a substrate 210, a gate line layer 220, the gate line layer 220 is disposed on the substrate 210; a gate insulating layer 230, the gate insulating layer 230 is disposed on the substrate 210 and covers the gate line layer 220; a semiconductor layer 240, the semiconductor layer 240 is disposed on a side of the gate insulating layer 230 away from the substrate 210; and a source/drain electrode layer, the source/drain electrode layer is disposed on a side of the semiconductor layer 240 away from the substrate 210. Wherein materials of the gate line layer 220 and the source/drain electrode layer are both a conductive metal, the gate line layer 220 is a recrystallized gate line layer, and the source/drain electrode layer is a recrystallized source/drain electrode layer.

As shown in FIG. 6, the array substrate 210 further includes a barrier layer 221 disposed between the gate line layer 220 and the substrate 210. Specifically, in order to improve the conductivity of the array substrate 200, material of the gate line layer 220 is Cu, and in order to prevent Cu atoms in the gate line layer 220 from being diffused to other layers such as the gate insulating layer 230 under the action of a high temperature or an applied electric field, the performance of other device layers of the array substrate 200 is degraded or even ineffective, so that metal Mo having a high melting point, good thermal stability and electrical conductivity is selected as material of the barrier layer 221.

As shown in FIG. 6, the array substrate 210 further includes a source/drain electrode layer formed on the semiconductor layer 240, a protective layer 260 disposed on the source/drain electrode layer and the semiconductor layer 240, and a pixel electrode layer 270 disposed on the protective layer 260. The source/drain electrode layer includes a source electrode 250 and a drain electrode 251, and the pixel electrode layer 270 is connected to the drain electrode 251 through a first via hole on the protective layer 260.

In some other embodiments, materials of gate line layer and the source/drain electrode layer include, but not limited to, Cu, Al, or Mo, or an alloy of two or more than any two metals of Cu, Al, and Mo.

In the embodiment of the present disclosure, the gate line layer 220 deposited on the substrate 210 and the source electrode 250 and the drain electrode 251 disposed on the semiconductor layer 240 are subjected to a heat treatment process to recrystallize the metal grains therein. After the gate line layer 220, the source electrode 250, and the drain electrode 251 are recrystallized from the molten state, sizes of metal grains become larger, so that the grain boundaries and defects in the gate line layer 220 and the source/drain electrode layer are reduced, thereby reducing the degree of scattering of electrons during the transmission in the gate line layer 220, the source electrode 250, and the drain electrode 251, reducing the resistivity of the gate line layer 220, the source electrode 250, and the drain electrode 251, and improving the conductivity of the gate line layer 220, the source electrode 250, the drain electrode 251, and the array substrate 100. Due to the improvement of the conductivity of the gate line layer 220, the source electrode 250, the drain electrode 251, the thickness of the gate line layer 220 and the source/drain electrode layer can be reduced.

As described above, although the present disclosure has been disclosed with the preferred embodiments thereof, the above preferred embodiments are not intended to limit the disclosure, those skilled in the art will appreciate that various modifications, additions, and substitutions are possible, without departing from the scope and the spirit of the disclosure. Accordingly, the scope of the present disclosure is intended to be defined only by reference to the claims.

What is claimed is:

1. A method of fabricating an array substrate, comprising a plurality of steps of:
step S10: providing a substrate, and depositing and forming a metal layer on the substrate;
step S20: patterning the metal layer to form metal traces; and
step S30: disposing the substrate in a vacuum chamber, and performing a heat treatment process to recrystallize the metal traces.

2. The method as claimed in claim 1, wherein material of the metal layer comprises Cu, Al, or Mo, or an alloy of two or more than two metals of Cu, Al, and Mo.

3. The method as claimed in claim 1, wherein the metal layer comprises a first metal layer and a second metal layer, the first metal layer is disposed on the substrate, and the second metal layer is disposed on a side of the first metal layer away from the substrate.

4. The method as claimed in claim 3, wherein material of the first metal layer is Mo, a thickness of the first metal layer ranges from 100 A to 1000 A, material of the second metal layer is Cu, and a thickness of the second metal layer ranges from 1000 A to 10000 A.

5. The method as claimed in claim 4, wherein in the step S30, the substrate is heat-treated at a temperature ranging from 200° C. to 450° C.

6. The method as claimed in claim 5, wherein in the step S30, the substrate is heat-treated for 5 minutes to 300 minutes.

7. The method as claimed in claim 6, wherein the method further comprises:
step S40: depositing and forming a gate insulating layer and a semiconductor layer on the metal layer in order;
step S50: depositing and forming a source/drain electrode layer on the semiconductor layer, and patterning the source/drain electrode layer to form a source electrode and a drain electrode;
step S60: disposing the substrate in the vacuum chamber, and performing a heat treatment process to recrystallize the source electrode and the drain electrode; and
step S70: depositing and forming a protective layer and a pixel electrode layer on the source electrode, the drain electrode, and the semiconductor layer.

8. The method as claimed in claim 1, wherein in the step 10, the metal layer is deposited by physical vapor deposition.

9. A method of fabricating an array substrate, comprising a plurality of steps of:
step S10: providing a substrate, and depositing and forming a first metal layer and a second metal layer on the substrate in order, the first metal layer being disposed on the substrate, and the second metal layer being disposed on a side of the first metal layer away from the substrate;
step S20: patterning the first metal layer and the second metal layer to form metal traces; and
step S30: disposing the substrate in a vacuum chamber, and performing a heat treatment process to recrystallize the metal traces.

10. The method as claimed in claim 9, wherein materials of the first metal layer and the second metal layer comprise Cu, Al, or Mo, or an alloy of two or more than two metals of Cu, Al, and Mo.

11. The method as claimed in claim 10, wherein material of the first metal layer is Mo, a thickness of the first metal layer ranges from 100 A to 1000 A, material of the second metal layer is Cu, and a thickness of the second metal layer ranges from 1000 A to 10000 A.

12. The method as claimed in claim 9, wherein in the step S30, the substrate is heat-treated at a temperature ranging from 200° C. to 450° C.

13. The method as claimed in claim 12, wherein in the step S30, the substrate is heat-treated for 5 minutes to 300 minutes.

14. The method as claimed in claim 13, wherein the method further comprises:
step S40: depositing and forming a gate insulating layer and a semiconductor layer on the metal layer in order;
step S50: depositing and forming a source/drain electrode layer on the semiconductor layer, and patterning the source/drain electrode layer to form a source electrode and a drain electrode;
step S60: disposing the substrate in the vacuum chamber, and performing a heat treatment process to recrystallize the source electrode and the drain electrode; and
step S70: depositing and forming a protective layer and a pixel electrode layer on the source electrode, the drain electrode, and the semiconductor layer.

15. The method as claimed in claim 9, wherein in the step 10, the metal layers are deposited by physical vapor deposition.

16. An array substrate, comprising:
a substrate;
a gate line layer disposed on the substrate;
a gate insulating layer disposed on the substrate and covering the gate line layer;
a semiconductor layer disposed on a side of the gate insulating layer away from the substrate; and
a source/drain electrode layer disposed on a side of the semiconductor layer away from the substrate;
wherein materials of the gate line layer and the source/drain electrode layer are both a conductive metal, the gate line layer is a recrystallized gate line layer, and the source/drain electrode layer is a recrystallized source/drain electrode layer.

17. The array substrate as claimed in claim 16, wherein materials of gate line layer and the source/drain electrode layer comprise Cu, Al, or Mo, or an alloy of two or more than two metals of Cu, Al, and Mo.
